(19) United States
(12) Patent Application Publication
(10) Pub. No.: US 2012/0003812 A1
(43) Pub. Date: Jan. 5, 2012

(54) METHOD OF MANUFACTURING SEMICONDUCTOR SUBSTRATE

(75) Inventors: Makoto Sasaki, Hyogo (JP); Shin Harada, Osaka (JP); Taro Nishiguchi, Hyogo (JP); Kyoko Okita, Hyogo (JP); Yasuo Namikawa, Hyogo (JP)

(73) Assignee: SUMITOMO ELECTRIC INDUSTRIES, LTD., Osaka-shi, Osaka (JP)

(21) Appl. No.: 13/256,455

(22) PCT Filed: Sep. 28, 2010
(86) PCT No.: PCT/JP2010/066827

§ 371 Date: Sep. 14, 2011

(30) Foreign Application Priority Data
Nov. 24, 2009 (JP) 2009-266522

(51) Int. Cl. H01L 21/04

(52) U.S. Cl. 438/455; 257/E21.054

(57) ABSTRACT

A plurality of silicon carbide substrates and a support portion are heated. A temperature of a first radiation plane facing the plurality of silicon carbide substrates in a first space extending from the plurality of silicon carbide substrates in a direction perpendicular to one plane and away from the support portion is set to a first temperature. A temperature of a second radiation plane facing the support portion in a second space extending from the support portion in a direction perpendicular to one plane and away from the plurality of silicon carbide substrates is set to a second temperature higher than the first temperature. A temperature of a third radiation plane facing the plurality of silicon carbide substrates in a third space extending from a gap among the plurality of silicon carbide substrates along one plane is set to a third temperature lower than the second temperature.

### TECHNICAL FIELD

The present invention relates to a method of manufacturing a semiconductor substrate and particularly to a method of manufacturing a semiconductor substrate including a silicon carbide substrate.

### BACKGROUND ART

An SiC substrate has recently increasingly been adopted as a semiconductor substrate used for manufacturing a semiconductor device. SiC has a bandgap wider than Si (silicon) that has more commonly been used. Therefore, a semiconductor device including an SiC substrate is advantageous in a high reverse breakdown voltage, a low ON resistance and less lowering in characteristics in an environment at a high temperature.

In order to efficiently manufacture a semiconductor device, a substrate is required to have a size not smaller than a certain size. According to U.S. Pat. No. 7,314,520 (Patent Document 1), an SiC substrate not smaller than 76 mm (3 inches) can be manufactured.

### PRIOR ART DOCUMENTS

### Patent Documents

Patent Document 1: U.S. Pat. No. 7,314,520

### SUMMARY OF THE INVENTION

### Problems to be Solved by the Invention

A size of an SiC substrate industrially remains as small as approximately 100 mm (4 inches) and hence it has not yet been able to efficiently manufacture a semiconductor device with the use of a large-sized substrate. In making use of characteristics of a plane other than a (0001) plane in particular in hexagonal SiC, the problem above is particularly serious, which will be described below.

An SiC substrate having fewer defects is normally manufactured by cutting an SiC ingot obtained by (0001) plane growth in which stacking faults are less likely. Therefore, an SiC substrate having a plane orientation other than the (0001) plane is cut in non-parallel to a growth surface. It is thus difficult to secure a sufficient size of a substrate or a most part of an ingot cannot effectively be made use of. Thus, it is particularly difficult to efficiently manufacture a semiconductor device using a plane other than the (0001) plane of SiC.

Instead of increase in size of an SiC substrate with such difficulties, use of a semiconductor substrate having a support portion and a plurality of small SiC substrates arranged thereon is possible. This semiconductor substrate can be increased in size as necessary, by increasing the number of SiC substrates.

In this semiconductor substrate, however, a gap is created between adjacent SiC substrates. In this gap, foreign matters are likely to be introduced during a process for manufacturing a semiconductor device including this semiconductor substrate. These foreign matters are represented, for example, by a cleaning liquid or abrasives used in the process for manufacturing a semiconductor device or dust in an atmosphere. Such foreign matters cause lowering in manufacturing yield and resulting lowering in efficiency in manufacturing a semiconductor device.

The present invention was made in view of the above-described problems, and an object of the present invention is to provide a method of manufacturing a large-sized semiconductor substrate allowing manufacturing of a semiconductor device in good yield.

### Means for Solving the Problems

A method of manufacturing a semiconductor substrate according to the present invention has the following steps.

A plurality of silicon carbide substrates having first and second silicon carbide substrates and a support portion are prepared. The first silicon carbide substrate has a first back surface facing the support portion and located on one plane, a first front surface opposed to the first back surface, and a first side surface connecting the first back surface and the first front surface to each other. The second silicon carbide substrate has a second back surface facing the support portion and located on one plane, a second front surface opposed to the second back surface, and a second side surface connecting the second back surface and the second front surface to each other. The second side surface is arranged such that a gap having an opening between the first and second front surfaces is formed between the second side surface and the first side surface. The support portion and the first and second silicon carbide substrates are heated such that a sublimate is generated from the first and second side surfaces and a bonded portion closing the opening is formed thereby. The heating step has the following steps. A temperature of a first radiation plane facing the plurality of silicon carbide substrates in a first space extending from the plurality of silicon carbide substrates in a direction perpendicular to one plane and away from the support portion is set to a first temperature. A temperature of a second radiation plane facing the support portion in a second space extending from the support portion in a direction perpendicular to one plane and away from the plurality of silicon carbide substrates is set to a second temperature higher than the first temperature. A temperature of a third radiation plane facing the plurality of silicon carbide substrates in a third space extending from the gap along one plane is set to a third temperature lower than the second temperature.

According to the present manufacturing method, the temperature of the third radiation plane facing the plurality of silicon carbide substrates in the third space is set to the third temperature lower than the second temperature. Therefore, influence by heat radiation from the third radiation plane to the gap is less than that by heat radiation from the second radiation plane having the second temperature. Thus, disturbance of a temperature gradient along the gap produced by temperature difference between the first and second radiation planes, due to heat radiation from the third radiation plane, becomes less. Consequently, since the temperature gradient above is more reliably formed, a sublimate closing the opening of the gap can more reliably be generated. Namely, the opening of the gap in the semiconductor substrate obtained with the present manufacturing method is more reliably closed. Therefore, in a process for manufacturing a semiconductor device including this semiconductor substrate, introduction of foreign matters into the gap is less likely and hence lowering in yield attributed to the foreign matters is suppressed. In addition, the semiconductor substrate can readily be increased in size by increasing the number of silicon carbide substrates. Thus, a large-sized semiconductor substrate allowing manufacturing of a semiconductor device in good yield is obtained.

Preferably, the third temperature is lower than the first temperature. Thus, influence by heat radiation from the third radiation plane to the gap is less than that by heat radiation from the first radiation plane having the first temperature. Therefore, disturbance of the temperature gradient above due to heat radiation from the third radiation plane can further be lessened.

Preferably, the step of preparing the plurality of silicon carbide substrates and the support portion is performed by preparing a composite substrate having the support portion and the first and second silicon carbide substrates, and each of the first and second back surfaces of the composite substrate is bonded to the support portion.

Preferably, the manufacturing method above further includes the step of bonding each of the first and second back surfaces to the support portion. The step of bonding each of the first and second back surfaces is performed simultaneously with the step for forming the bonded portion.

Preferably, the support portion is composed of silicon carbide.

Preferably, the manufacturing method above further includes the step of depositing a sublimate from the support portion on the bonded portion in the gap having the opening closed by the bonded portion.

Preferably, the step of depositing a sublimate from the support portion on the bonded portion is performed such that the gap as a whole having the opening closed by the bonded portion moves into the support portion.

Preferably, the heating step is performed with a heat source arranged outside the third space.

Preferably, the heat source is arranged in a space including the support portion, of the spaces separated from each other by the third space.

Preferably, a material forming the third radiation plane is lower in thermal conductivity than a material forming the second radiation plane.

Preferably, the material forming the third radiation plane is lower in thermal conductivity than a material forming the first radiation plane.

Preferably, the heating step is performed with first to third heat generation elements arranged in the first to third spaces respectively.

Preferably, the first to third heat generation elements are controlled independently of one another.

Preferably, the method of manufacturing a semiconductor substrate above further has the step of polishing each of the first and second front surfaces. Thus, since the first and second front surfaces serving as the front surface of the semiconductor substrate can be a flat surface, a high-quality film can be formed on this flat surface of the semiconductor substrate.

Preferably, each of the first and second back surfaces is a surface formed by slicing. Namely, each of the first and second back surfaces is a surface formed by slicing but not polished subsequently. Irregularities are thus provided on each of the first and second back surfaces. Therefore, in a case where the support portion is provided by using a sublimation method on the first and second back surfaces, a space within a recess in these irregularities can be used as a cavity where a sublimation gas spreads.

Preferably, the heating step is performed in an atmosphere having a pressure higher than 10⁻¹ Pa and lower than 10⁴ Pa.

### Effects of the Invention

As can clearly be seen from the description above, according to the present invention, a method of manufacturing a large-sized semiconductor substrate allowing manufacturing of a semiconductor device in good yield can be provided.

### BRIEF DESCRIPTION OF THE DRAWINGS

FIG. 1 is a plan view schematically showing a construction of a semiconductor substrate in Embodiment 1 of the present invention.

FIG. 2 is a schematic cross-sectional view along the line II-II in FIG. 1.

FIG. 3 is a plan view schematically showing a first step in a method of manufacturing a semiconductor substrate in Embodiment 1 of the present invention.

FIG. 4 is a schematic cross-sectional view along the line IV-IV in FIG. 3.

FIG. 5 is a cross-sectional view schematically showing a second step in the method of manufacturing a semiconductor substrate in Embodiment 1 of the present invention.

FIG. 6 is a partial enlarged view of FIG. 5.

FIG. 7 is a schematic diagram for illustrating a manner of heat radiation in the method of manufacturing a semiconductor substrate in Embodiment 1 of the present invention.

FIG. 8 is a partial cross-sectional view schematically showing a third step in the method of manufacturing a semiconductor substrate in Embodiment 1 of the present invention.

FIG. 9 is a partial cross-sectional view schematically showing a fourth step in the method of manufacturing a semiconductor substrate in Embodiment 1 of the present invention.

FIG. 10 is a cross-sectional view schematically showing one step in a method of manufacturing a semiconductor substrate according to a comparative example.

FIG. 11 is a cross-sectional view schematically showing a first step in a method of manufacturing a semiconductor substrate in Embodiment 2 of the present invention.

FIG. 12 is a cross-sectional view schematically showing a second step in the method of manufacturing a semiconductor substrate in Embodiment 2 of the present invention.

FIG. 13 is a cross-sectional view schematically showing a third step in the method of manufacturing a semiconductor substrate in Embodiment 2 of the present invention.

FIG. 14 is a cross-sectional view schematically showing one step in a method of manufacturing a semiconductor substrate in a first variation of Embodiment 2 of the present invention.

FIG. 15 is a cross-sectional view schematically showing one step in a method of manufacturing a semiconductor substrate in a second variation of Embodiment 2 of the present invention.

FIG. 16 is a cross-sectional view schematically showing one step in a method of manufacturing a semiconductor substrate in a third variation of Embodiment 2 of the present invention.

FIG. 17 is a plan view schematically showing a construction of a semiconductor substrate in Embodiment 4 of the present invention.

FIG. 18 is a schematic cross-sectional view along the line XVIII-XVIII in FIG. 17.

FIG. 19 is a plan view schematically showing a construction of a semiconductor substrate in Embodiment 5 of the present invention.

FIG. 20 is a schematic cross-sectional view along the line XX-XX in FIG. 19.

FIG. 21 is a cross-sectional view schematically showing one step in a method of manufacturing a semiconductor substrate in Embodiment 6 of the present invention.

FIG. 22 is a cross-sectional view schematically showing one step in a method of manufacturing a semiconductor substrate in Embodiment 7 of the present invention.

FIG. 23 is a cross-sectional view showing one step in a method of manufacturing a semiconductor substrate according to a comparative example of Embodiment 7 of the present invention.

FIG. 24 is a cross-sectional view schematically showing one step in a method of manufacturing a semiconductor substrate in Embodiment 8 of the present invention.

FIG. 25 is a cross-sectional view schematically showing one step in a method of manufacturing a semiconductor substrate in Embodiment 9 of the present invention.

### MODES FOR CARRYING OUT THE INVENTION

An embodiment of the present invention will be described hereinafter with reference to the drawings.

### Embodiment 1

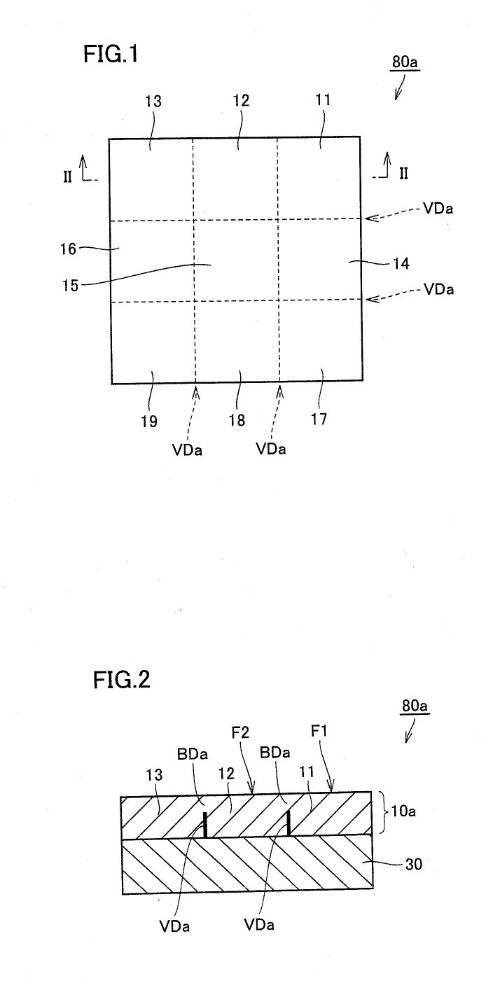

Referring to FIGS. 1 and 2, a semiconductor substrate 80a according to the present embodiment has a support portion 30 and a supported portion 10a supported by support portion 30. Supported portion 10a has SiC substrates 11 to 19 (silicon carbide substrates).

Support portion 30 connects back surfaces of respective SiC substrates 11 to 19 (surfaces opposite to the surfaces shown in FIG. 1) to one another, so that SiC substrates 11 to 19 are fixed to one another. Each of SiC substrates 11 to 19 has a front surface exposed at the same plane, and for example, SiC substrates 11 and 12 has first and second front surfaces F1 and F2 respectively (FIG. 2). Thus, semiconductor substrate 80a has a surface greater than each of SiC substrates 11 to 19. Therefore, a semiconductor device can more efficiently be manufactured in a case where semiconductor substrate 80a is used than in a case where each of SiC substrates 11 to 19 alone is used.

In addition, support portion 30 is preferably made of a material capable of withstanding a temperature not lower than 1800° C., and it is made, for example, of silicon carbide, carbon or a refractory metal. An exemplary refractory metal is molybdenum, tantalum, tungsten, niobium, iridium, ruthenium, or zirconium. It is noted that use of silicon carbide among the above as a material for support portion 30 can bring a physical property of support portion 30 closer to that of SIC substrates 11 to 19.

Moreover, there is a gap VDa among SiC substrates 11 to 19 in supported portion 10a, and a front surface side (an upper side in FIG. 2) of this gap VDa is closed by a bonded portion BDa. Bonded portion BDa includes a portion located between first and second front surfaces F1 and F2, so that first and second front surfaces F1 and F2 are smoothly connected to each other.

A method of manufacturing semiconductor substrate 80a in the present embodiment will now be described. For the sake of brevity of illustration below, only SiC substrates 11 and 12 among SiC substrates 11 to 19 may be mentioned, however, SiC substrates 13 to 19 are also addressed similarly to SiC substrates 11 and 12.

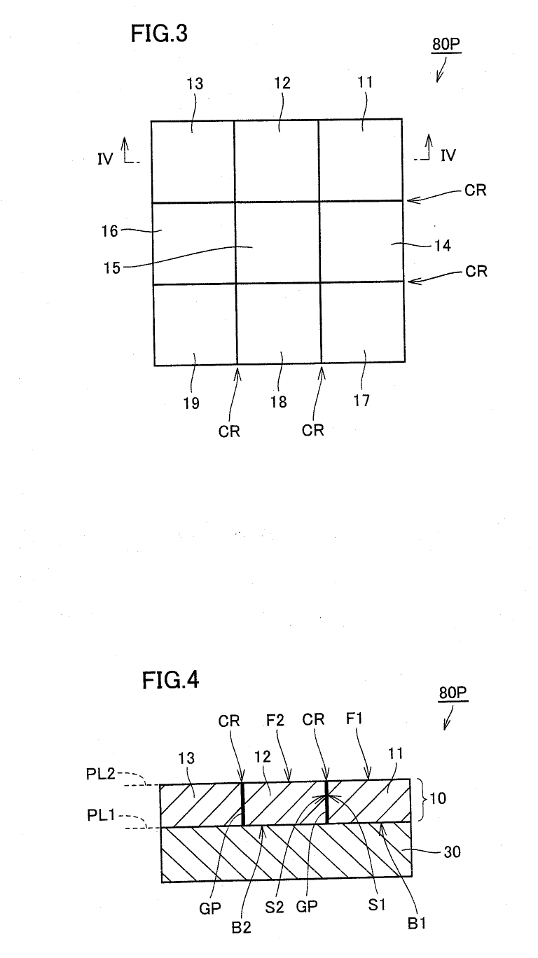

Referring to FIGS. 3 and 4, a composite substrate 80P is prepared. Composite substrate 80P has support portion 30 and an SiC substrate group 10 (a plurality of silicon carbide substrates). SiC substrate group 10 includes SiC substrate 11 (a first silicon carbide substrate) and SiC substrate 12 (a second silicon carbide substrate).

SiC substrate 11 has a first back surface B1 facing support portion 30 and located on a first plane PL1 (one plane), a first front surface F1 opposed to first back surface B1 and located on a second plane PL2, and a first side surface S1 connecting first back surface B1 and first front surface F1 to each other. First back surface B1 is bonded to support portion 30. Similarly, SiC substrate 12 has a second back surface B2 facing support portion 30 and located on first plane PL1, a second front surface F2 opposed to second back surface B2 and located on second plane PL2, and a second side surface S2 connecting second back surface B2 and second front surface F2 to each other. Second back surface B2 is bonded to support portion 30. Second side surface S2 is arranged such that a gap GP having an opening CR between first and second front surfaces F1 and F2 is formed between second side surface S2 and first side surface S1.

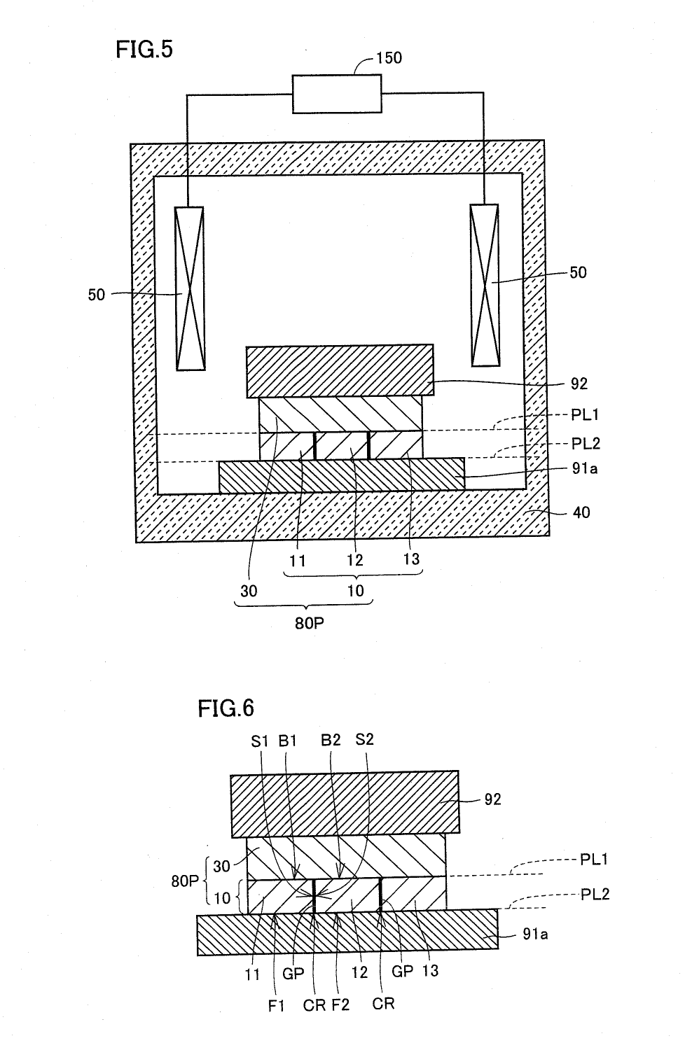

Referring to FIGS. 5 and 6, a heating apparatus for heating composite substrate 80P is prepared. The heating apparatus has a heat-insulating vessel 40, a heater (heat source) 50, first and second heating elements 91a and 92, and a heater power supply 150. Heat-insulating vessel 40 is formed of a highly heat-insulating material. Heater 50 is, for example, an electric resistance heater. The first and second heating elements have a function to absorb radiant heat from heater 50 and to radiate obtained heat toward composite substrate 80P. Namely, first and second heating elements 91a and 92 have a function to heat composite substrate 80P. First and second heating elements 91a and 92 are formed, for example, of graphite low in porosity.

Then, first heating element 91a, composite substrate 80P, and second heating element 92 are accommodated in heat-insulating vessel 40 in which heater 50 is arranged. Positional relation among these will be described below.

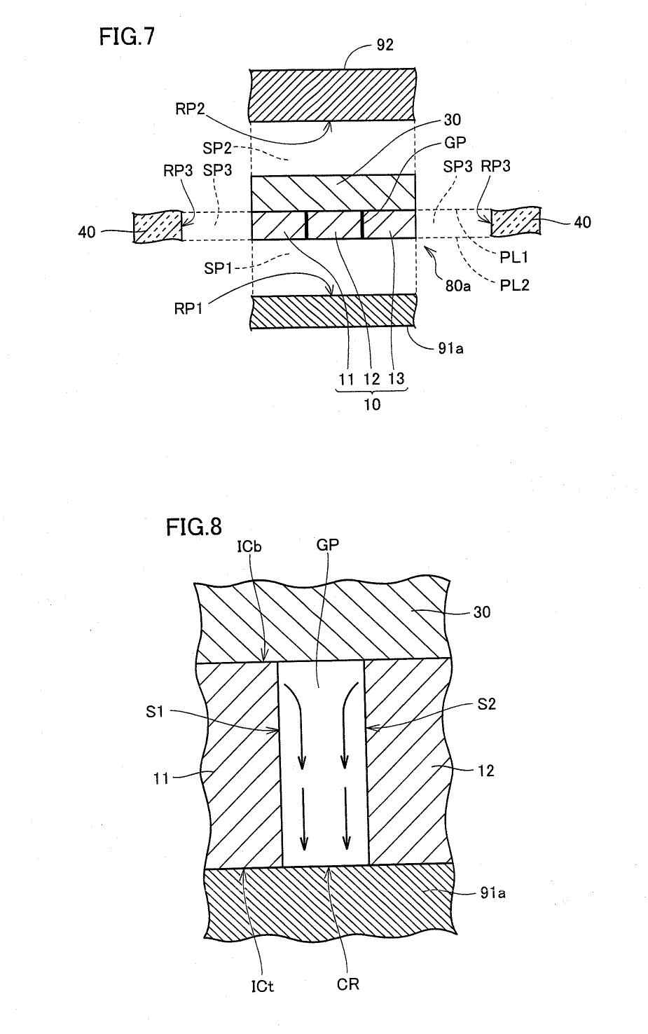

First, composite substrate 80P is arranged on heating element 91a such that SiC substrate group 10 faces a first radiation plane RP1 of first heating element 91a. Thus, in a first space SP1 (FIG. 7) extending from SiC substrate group 10 in a direction perpendicular to first plane PL1 and away from support portion 30, first radiation plane RP1 faces SiC substrate group 10.

Secondly, a second radiation plane RP2 of second heating element 92 is arranged on composite substrate 80P so as to face support portion 30. Each of first and second heating elements 91a and 92 is arranged outside a third space SP3 (FIG. 7) extending from gap GP along first plane PL1. Thus, in a second space SP2 (FIG. 7) extending from support portion 30 in a direction perpendicular to first plane PL1 and away from SiC substrate group 10, second radiation plane RP2 faces support portion 30.

Thirdly, heater 50 is arranged outside third space SP3 (FIG. 7) extending from gap GP along first plane PL1. More specifically, heater 50 is arranged in a space including support portion 30 (a space above first plane PL1 in FIG. 5), of the spaces separated from each other by the third space. Thus, in third space SP3 (FIG. 7), a radiation plane RP3 of heat-insulating vessel 40 faces SiC substrate group 10.

Then, support portion 30 and SiC substrates 11 and 12 are heated by heater 50. This heating step will be described below.

Initially, an atmosphere in heat-insulating vessel 40 is set to an atmosphere obtained by reducing an atmospheric pressure. Preferably, a pressure of the atmosphere is set to a pressure higher than 10⁻¹ Pa and lower than 10⁴ Pa.

It is noted that the atmosphere above may be an inert gas atmosphere. As an inert gas, for example, a noble gas such as He or Ar, a nitrogen gas, or a gas mixture of a noble gas and a nitrogen gas can be used. In using this gas mixture, a ratio of the nitrogen gas is set, for example, to 60%. In addition, a pressure in a treatment chamber is set preferably to 50 kPa or lower and more preferably to 10 kPa or lower.

Then, respective temperatures of first radiation plane RP1 of first heating element 91a, second radiation plane RP2 of second heating element RP2, and third radiation plane RP3 of heat-insulating vessel 40 are set to first to third temperatures. The second temperature is set higher than the first temperature. In addition, the third temperature is set lower than the second temperature and preferably lower than the first temperature.

Referring to FIG. 8, as the second temperature is set higher than the first temperature, a temperature on a second side ICb which is a side of SiC substrate group 10 facing support portion 30 is higher than a temperature on a first side ICt which is a side of SiC substrate group 10 facing first heating element 91a. Namely, a temperature gradient is produced in a direction of thickness of SiC substrate group 10 (a vertical direction in FIG. 8). This temperature gradient causes generation of a sublimate and travel thereof as shown with an arrow in the drawing, from a region within gap GP at a relatively high temperature closer to second side ICb to a region at a relatively low temperature closer to first side ICt, of the surfaces of SiC substrates 11 and 12, that is, first and second side surfaces S1 and S2.

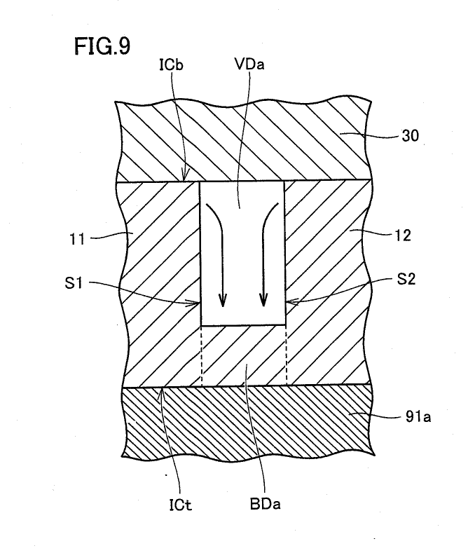

Referring further to FIG. 9, the sublimate above forms bonded portion BDa closing opening CR in such a manner as connecting side surfaces S1 and S2 to each other. Consequently, gap GP (FIG. 8) becomes a gap VDa (FIG. 9) closed by bonded portion BDa.

It is noted that experiments for verifying heating temperatures above were conducted. Then, there were such problems that bonded portion BDa was not sufficiently formed when a temperature of heater 50 was set to 1600° C. and that SiC substrates 11 and 12 were damaged when it was set to 3000° C. These problems, however, were not seen at each temperature of 1800° C., 2000° C., and 2500° C.

In addition, a pressure of an atmosphere during heating above was verified, with a set temperature of heater 50 being fixed at 2000° C. Consequently, there was a problem that no bonded portion BDa was formed at 100 kPa and bonded portion BDa was less likely to be formed at 50 kPa, however, this problem was not seen at each pressure of 10 kPa, 100 Pa, 1 Pa, 0.1 Pa, and 0.0001 Pa.

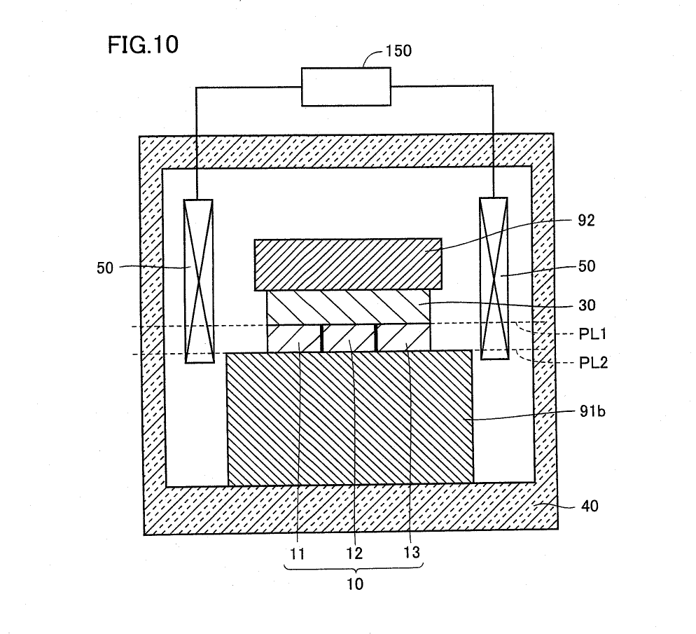

Then, a case where a part of heater 50 is assumed to be located in a space between first and second planes PL1 and PL2 will be described as a comparative example (FIG. 10). In this case, at least a part of third radiation plane RP3 (FIG. 7) is implemented not by heat-insulating vessel 40 but by heater 50. Consequently, a temperature of at least a part of third radiation plane RP3 becomes higher than a temperature of second radiation plane RP2, and hence strong heat radiation from third radiation plane RP3 to gap GP occurs. Influence by this strong heat radiation disturbs the temperature gradient between first and second sides ICt and ICb in gap GP. Consequently, since travel of the sublimate (the arrow in FIGS. 8 and 9) is disturbed, bonded portion BDa is not formed or formation of bonded portion BDa takes time. Namely, in the comparative example, opening CR is less likely to be closed.

In contrast, according to the present embodiment, since the temperature of third radiation plane RP3 (FIG. 7) (third temperature) is lower than the temperature of second radiation plane RP2 (second temperature), influence by heat radiation from third radiation plane RP3 to gap GP is weaker than that by heat radiation from second radiation plane RP2. Therefore, disturbance of the temperature gradient along gap GP produced by temperature difference between first and second radiation planes RP1 and RP2, due to heat radiation from third radiation plane RP3, is lessened. Consequently, since the temperature gradient above is more reliably produced, bonded portion BDa formed by the sublimate closing opening CR of the gap can more reliably be formed. Namely, the opening of gap VDa of semiconductor substrate 80a (FIGS. 1 and 2) obtained with the present manufacturing method is more reliably closed by bonded portion BDa. Therefore, in the process for manufacturing a semiconductor device including semiconductor substrate 80a, introduction of foreign matters in gap VDa is less likely and hence lowering in yield attributed to foreign matters is suppressed.

In addition, semiconductor substrate 80a (FIG. 2) includes both of first and second front surfaces F1 and F2 of the respective SiC substrates, as a substrate surface on which a semiconductor device such as a transistor is to be formed. Namely, semiconductor substrate 80a has a substrate surface greater than in a case where any of SiC substrates 11 and 12 is used alone. Thus, a semiconductor device can efficiently be manufactured with the use of semiconductor substrate 80a.

Though SiC substrate group 10 is arranged on first heating element 91a in the present embodiment, a flexible member such as a graphite sheet may be arranged between SiC substrate group 10 and first heating element 91a. As this member closes opening CR (FIG. 8), travel of the sublimate (the arrow in FIG. 8) is more reliably blocked in opening CR and hence bonded portion BDa is more likely to be formed in opening CR.

In addition, before bonded portion BDa is formed, a protection film such as a resist film may be formed in advance on first and second front surfaces F1 and F2. Thus, sublimation and resolidification on first and second front surfaces F1 and F2 can be avoided. Therefore, roughening of first and second front surfaces F1 and F2 can be prevented.

### Embodiment 2

In the present embodiment, a method of manufacturing composite substrate 80P (FIGS. 3 and 4) employed in Embodiment 1 will be described in detail, in particular with reference to a case where support portion 30 is composed of silicon carbide. For the sake of brevity of illustration below, only SiC substrates 11 and 12 among SiC substrates 11 to 19 (FIGS. 3 and 4) may be mentioned, however, SiC substrates 13 to 19 are also addressed similarly to SiC substrates 11 and 12.

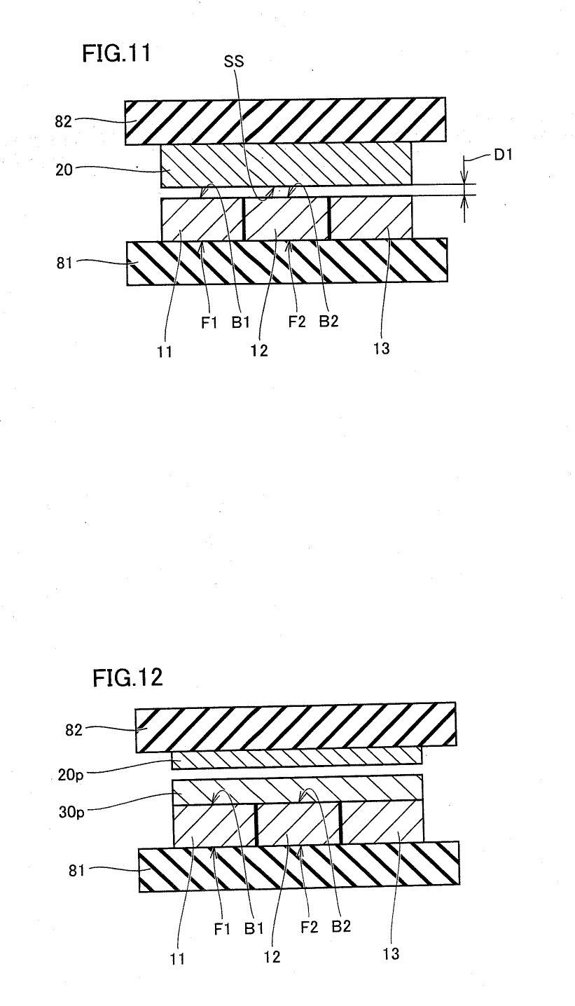

Referring to FIG. 11, SiC substrates 11 and 12 each having a single-crystal structure are prepared. Specifically, for example, SiC substrates 11 and 12 are prepared by cutting an SiC ingot grown on the (0001) plane in hexagonal system along a (03-38) plane. Preferably, roughness Ra of back surfaces B1 and B2 is not greater than 100 μm.

Then, SiC substrates 11 and 12 are arranged on a first heating element 81 in a treatment chamber such that each of back surfaces B1 and B2 is exposed in one direction (upward in FIG. 11). Namely, SiC substrates 11 and 12 are arranged side by side when viewed two-dimensionally.

Preferably, arrangement above is done such that back surfaces B1 and B2 are flush with each other or first and second front surfaces F1 and F2 are flush with each other.

In addition, preferably, a shortest distance between SiC substrates 11 and 12 (a shortest distance in a lateral direction in FIG. 11) is set to 5 mm or shorter, more preferably to 1 mm or shorter, further preferably to 100 μm or shorter, and still further preferably to 10 μm or shorter. Specifically, for example, substrates identical in rectangular shape are arranged in matrix at a distance not greater than 1 mm from one another.

Then, support portion 30 (FIG. 4) connecting back surfaces B1 and B2 to each other is formed as follows.

Initially, each of back surfaces B1 and B2 exposed in one direction (upward in FIG. 11) and a surface SS of a solid source material 20 arranged in one direction (above in FIG. 11) with respect to back surfaces B1 and B2 are opposed to each other at a distance D1 from each other. Preferably, an average value of distance D1 is not smaller than 1 μm and not greater than 1 cm.

Solid source material 20 is made of SiC and it is preferably a solid of a lump of silicon carbide specifically implemented, for example, as an SiC wafer. A crystal structure of SiC representing solid source material 20 is not particularly limited. In addition, preferably, surface SS of solid source material 20 has roughness Ra not greater than 1 mm.

In order to more reliably provide distance D1 (FIG. 11), a spacer 83 (FIG. 14) having a height corresponding to distance D1 may be employed. This method is particularly effective when the average value of distance D1 is not smaller than about 100 μm.

Then, first heating element 81 heats SiC substrates 11 and 12 to a prescribed substrate temperature. In addition, a second heating element 82 heats solid source material 20 to a prescribed source material temperature. As solid source material 20 is heated to the source material temperature, SiC sublimes at surface SS of the solid source material so that a sublimate, that is, a gas, is generated. This gas is supplied from one direction (above in FIG. 11) onto each of back surfaces B1 and B2.

Preferably, the substrate temperature is set lower than the source material temperature, and more preferably temperature difference therebetween is not smaller than 1° C. and not greater than 100° C. In addition, preferably, the substrate temperature is not lower than 1800° C. and not higher than 2500° C.

Referring to FIG. 12, the gas supplied as above is solidified and recrystallized on each of back surfaces B1 and B2. Thus, a support portion 30p connecting back surfaces B1 and B2 to each other is formed. In addition, as solid source material 20 (FIG. 11) is consumed and made smaller to thereby become a solid source material 20p.

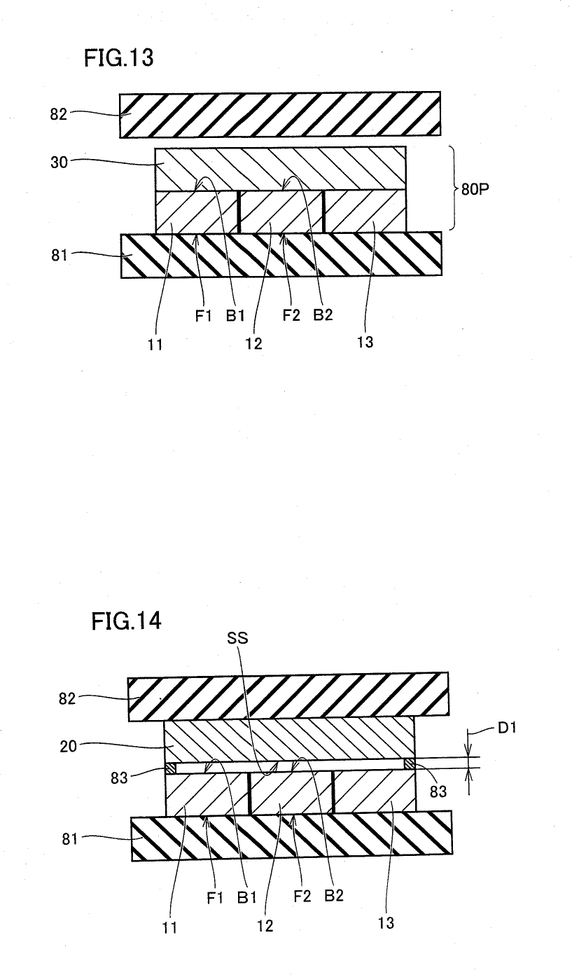

Referring mainly to FIG. 13, as sublimation further proceeds, solid source material 20p (FIG. 12) vanishes. Thus, support portion 30 connecting back surfaces B1 and B2 to each other is formed.

Preferably, when support portion 30 is formed, an atmosphere in the treatment chamber is an inert gas. As an inert gas, for example, a noble gas such as He or Ar, a nitrogen gas, or a gas mixture of a noble gas and a nitrogen gas can be used. In using this gas mixture, a ratio of the nitrogen gas is set, for example, to 60%. In addition, a pressure in the treatment chamber is set preferably to 50 kPa or lower and more preferably to 10 kPa or lower.

In addition, preferably, support portion 30 has a single-crystal structure. More preferably, inclination of a crystal plane of support portion 30 on back surface B1 with respect to a crystal plane of back surface B1 is not greater than 10°, and inclination of a crystal plane of support portion 30 on back surface B2 with respect to a crystal plane of back surface B2 is not greater than 10°. These relations of angle are readily realized, as support portion 30 is epitaxially grown on each of back surfaces B1 and B2.

It is noted that SiC substrate 11, 12 preferably has a hexagonal crystal structure and more preferably the crystal structure is 4H—SiC or 6H—SiC. In addition, SiC substrates 11 and 12 and support portion 30 are preferably formed of SiC single crystals identical in crystal structure.

Moreover, preferably, concentration in each of SiC substrates 11 and 12 is different from impurity concentration in support portion 30. More preferably, the impurity concentration in support portion 30 is higher than impurity concentration in each of SiC substrates 11 and 12. It is noted that SiC substrate 11, 12 has impurity concentration, for example, not lower than 5×10¹⁶ cm⁻³ and not higher than 5×10¹⁹ cm³. Meanwhile, support portion 30 has impurity concentration, for example, not lower than 5×10¹⁶ cm⁻³ and not higher than 5×10²¹ cm⁻³ For example, nitrogen or phosphorus can be employed as the impurity above.

In addition, preferably, an off angle of first front surface F1 with respect to the {0001} plane of SiC substrate 11 is not smaller than 50° and not greater than 65°, and an off angle of second front surface F2 with respect to the {0001} plane of the SiC substrate is not smaller than 50° and not greater than 65°.

More preferably, an angle between an off orientation of first front surface F1 and a <1-100> direction of SiC substrate 11 is not greater than 5° and an angle between an off orientation of second front surface F2 and a <1-100> direction of substrate 12 is not greater than 5°.

Further preferably, an off angle of first front surface F1 with respect to the {03-38} plane in the <1-100> direction of SiC substrate 11 is not smaller than −3° and not greater than 5°, and an off angle of second front surface F2 with respect to the {03-38} plane in the <1-100> direction of SiC substrate 12 is not smaller than −3° and not greater than 5°.

In the above, the “off angle of first front surface F1 with respect to the {03-38} plane in the <1-100> direction” refers to an angle formed between a normal of the {03-38} plane and an orthogonal projection of a normal of first front surface F1 onto a projection surface where the <1-100> direction and the <0001> direction extend, and the sign is positive when the orthogonal projection above is closer to parallel to the <1-100> direction, and the sign is negative when the orthogonal projection above is closer to parallel to the <0001> direction. This is also the case with the “off angle of second front surface F2 with respect to the {03-38} plane in the <1-100> direction.”

In addition, preferably, an angle between the off orientation of first front surface F1 and a <11-20> direction of substrate 11 is not greater than 5°, and an angle between the off orientation of second front surface F2 and a <11-20> direction of substrate 12 is not greater than 5°.

According to the present embodiment, since support portion 30 formed on each of back surfaces B1 and B2 is made of SiC similarly to SiC substrates 11 and 12, various physical properties are close between the SiC substrate and support portion 30. Therefore, warp or crack of composite substrate 80P (FIGS. 3 and 4) or semiconductor substrate 80a (FIGS. 1 and 2) due to difference in these various physical properties can be suppressed.

In addition, by employing a sublimation method, high-quality support portion 30 can quickly be formed. Further, if a close-space sublimation method is particularly employed as the sublimation method, support portion 30 can more uniformly be formed.

Moreover, as the average value of distance D1 (FIG. 11) between each of back surfaces B1 and B2 and the surface of solid source material 20 is not greater than 1 cm, film thickness distribution of support portion 30 can be less. Further, as the average value of this distance D1 is not smaller than 1 μm space where SiC sublimes can sufficiently be secured.

Furthermore, in the step of forming support portion 30, a temperature of SiC substrates 11 and 12 is set lower than a temperature of solid source material 20 (FIG. 11). Thus, SiC that sublimes can efficiently be solidified on SiC substrates 11 and 12.

In addition, preferably, the step of arranging SiC substrates 11 and 12 is performed such that a shortest distance between SiC substrates 11 and 12 is not greater than 1 mm. Thus, support portion 30 can be formed such that back surface B1 of SiC substrate 11 and back surface B2 of SiC substrate 12 are more reliably connected to each other.

Moreover, preferably, support portion 30 has a single-crystal structure. Various physical properties of support portion 30 are thus close to those of each of SiC substrates 11 and 12 similarly having a single-crystal structure.

Further preferably, inclination of the crystal plane of support portion 30 on back surface B1 with respect to the crystal plane of back surface B1 is not greater than 10°, and inclination of the crystal plane of support portion 30 on back surface B2 with respect to the crystal plane of back surface B2 is not greater than 10°. Anisotropy of support portion 30 can thus be close to anisotropy of each of SiC substrates 11 and 12.

In addition, preferably, each of SiC substrates 11 and 12 is different in impurity concentration from support portion 30. Thus, semiconductor substrate 80a (FIG. 2) having a two-layered structure different in impurity concentration can be obtained.

In addition, preferably, support portion 30 is higher in impurity concentration than each of SiC substrates 11 and 12. Therefore, support portion 30 can be lower in resistivity than each of SiC substrates 11 and 12. Thus, semiconductor substrate 80a suitable for manufacturing a semiconductor device in which a current flows in a direction of thickness of support portion 30, that is, a vertical semiconductor device, can be obtained.

In addition, preferably, an off angle of first front surface F1 with respect to the {0001} plane of SiC substrate 11 is not smaller than 50° and not greater than 65°, and an off angle of second front surface F2 with respect to the {0001} plane of SiC substrate 12 is not smaller than 50° and not greater than 65°. Thus, channel mobility at first and second front surfaces F1 and F2 can be improved as compared with a case where first and second front surfaces F1 and F2 are {0001} planes.

More preferably, an angle between the off orientation of first front surface F1 and the <1-100> direction of SiC substrate 11 is not greater than 5° and an angle between the off orientation of second front surface F2 and the <1-100> direction of SiC substrate 12 is not greater than 5°. Thus, channel mobility at first and second front surfaces F1 and F2 can further be improved.

Further preferably, an off angle of first front surface F1 with respect to the {03-38} plane in the <1-100> direction of SiC substrate 11 is not smaller than −3° and not greater than 5°, and an off angle of second front surface F2 with respect to the {03-38} plane in the <1-100> direction of SiC substrate 12 is not smaller than −3° and not greater than 5°. Thus, channel mobility at first and second front surfaces F1 and F2 can still further be improved.

In addition, preferably, an angle between the off orientation of first front surface F1 and the <11-20> direction of SiC substrate 11 is not greater than 5°, and an angle between the off orientation of second front surface F2 and the <11-20> direction of SiC substrate 12 is not greater than 5°. Thus, channel mobility at first and second front surfaces F1 and F2 can be improved as compared with a case where first and second front surfaces F1 and F2 are {0001} planes.

Though an SiC wafer has been exemplified as solid source material 20 in the above, solid source material 20 is not limited thereto, and for example, SiC powders or an SiC sintered object may be employed.

In addition, any element capable of heating an object may be employed as first and second heating elements 81 and 82, and for example, such an element of a resistance heating type as using a graphite heater or an element of an induction heating type can be employed.

In addition, in FIG. 11, each of back surfaces B1 and B2 is spaced apart from surface SS of solid source material 20 in its entirety. Each of back surfaces B1 and B2 may be spaced apart from surface SS of solid source material 20, while back surfaces B1 and B2 and surface SS of solid source material 20 are partially in contact with each other. Two variations corresponding to this case will be described below.

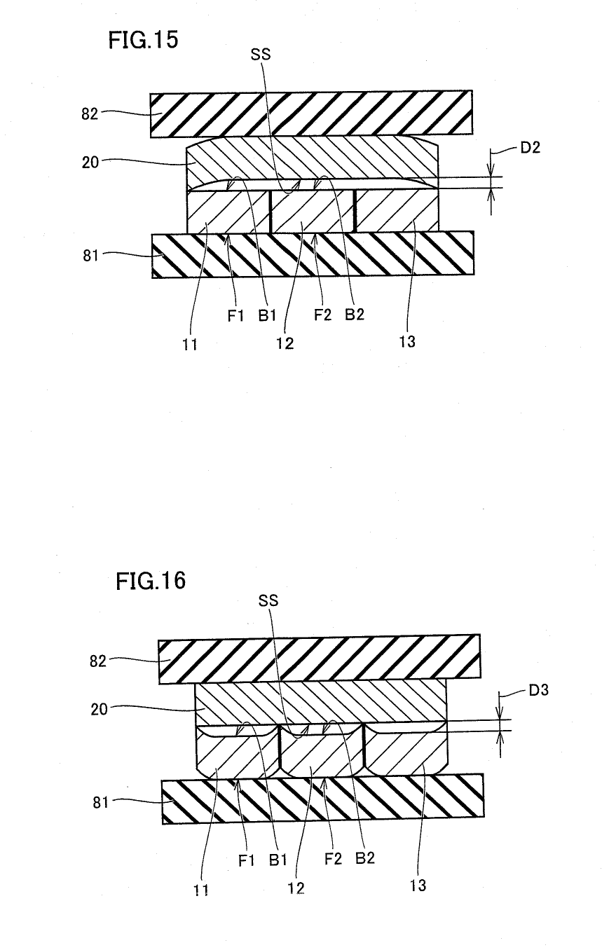

Referring to FIG. 15, in this example, warp of an SiC wafer representing solid source material 20 ensures the distance above. More specifically, in the present example, a distance D2 is locally zero, however, the average value unexceptionally exceeds zero. In addition, preferably, the average value of distance D2 is not smaller than 1 μm and not greater than 1 cm, similarly to the average value of distance D1.

Referring to FIG. 16, in this example, warp of SiC substrates 11 to 13 ensures the distance above. More specifically, in the present example, a distance D3 is locally zero, however, the average value unexceptionally exceeds zero. In addition, preferably, the average value of distance D3 is not smaller than 1 μm and not greater than 1 cm, similarly to the average value of distance D1.

It is noted that combination of the methods in FIGS. 15 and 16, that is, both of warp of the SiC wafer representing solid source material 20 and warp of SiC substrates 11 to 13, may ensure the distance above.

The method in each of FIGS. 15 and 16 or the method based on combination of both methods described above is particularly effective when the average value of the distance above is not greater than 100 μm.

In addition, in order to ensure the distance above, the back surface of each of SiC substrates 11 to 13 (for example, back surfaces B1 and B2) may be a surface formed by slicing. Namely, the back surface may be a surface formed by slicing but not polished subsequently. Thus, irregularities are provided on each back surface. Therefore, a space within a recess in these irregularities can be used for ensuring the distance above.

### Embodiment 3

In Embodiment 1, prior to formation of bonded portion BDa (FIG. 2), each of first and second back surfaces B1 and B2 is bonded in advance to support portion 30, for example, with the method according to Embodiment 2.

In contrast, in the present embodiment, bonding of each of first and second back surfaces B1 and B2 to support portion 30 is performed simultaneously with formation of bonded portion BDa. Namely, in the present embodiment, the step of bonding each of first and second back surfaces B1 and B2 of SiC substrate group 10 to support portion 30 is further included after the step of preparing support portion 30 and SiC substrate group 10, and this bonding step is performed simultaneously with the step of forming bonded portion BDa (FIG. 2).

It is noted that the present embodiment is otherwise substantially the same as Embodiment 1 and hence detailed description will not be provided.

According to the present embodiment, the step of bonding each of first and second back surfaces B1 and B2 to support portion 30 is performed simultaneously with the step of forming bonded portion BDa. Therefore, as compared with a case where these steps are individually performed, the process for manufacturing semiconductor substrate 80a (FIGS. 1 and 2) can be simplified.

In a variation of the present embodiment, solid source material 20 (FIG. 11) instead of support portion 30 (FIG. 5) may be prepared as the support portion prepared before heating, solid source material 20 and SiC substrate group 10 may be arranged as in Embodiment 2, and heater 50 may be arranged as in Embodiment 1. In addition, here, as in each variation of Embodiment 2, the construction in FIG. 15, the construction in FIG. 16, or a construction based on combination thereof may be employed.

### Embodiment 4

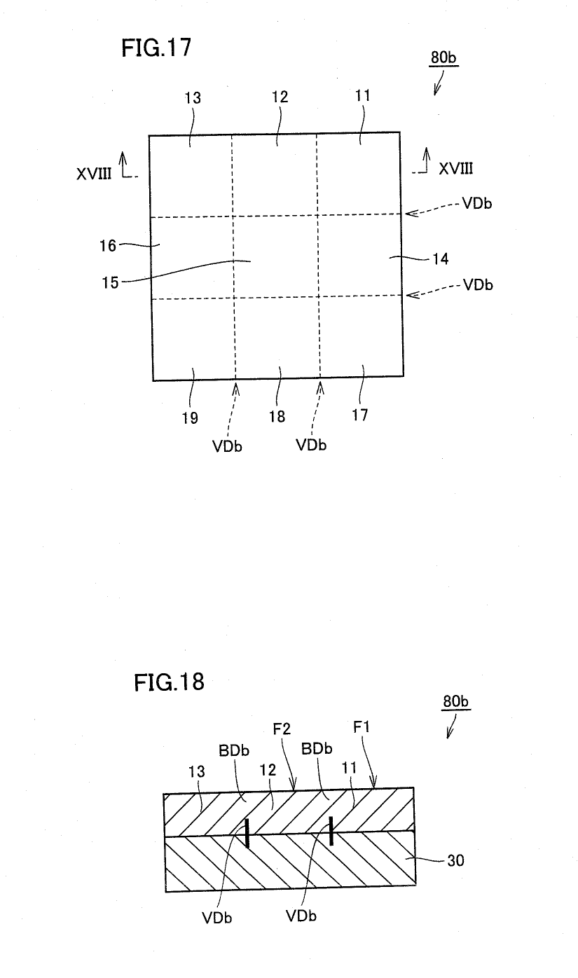

Referring to FIGS. 17 and 18, a semiconductor substrate 80b according to the present embodiment has a gap VDb closed by a bonded portion BDb instead of gap VDa (FIG. 2: Embodiments 1 to 3) closed by bonded portion BDa.

A method of manufacturing semiconductor substrate 80b will now be described.

In the present embodiment, support portion 30 is made of SiC, and even-after bonded portion BDa is formed as shown in FIG. 9, mass transfer involved with sublimation further continues. Consequently, sublimation from support portion 30 into closed gap VDa also occurs to an unignorable extent. Namely, a sublimate from support portion 30 is deposited on bonded portion BDa. Thus, gap VDa between SiC substrates 11 and 12 moves in such a manner as partially entering support portion 30, and hence gap VDb (FIG. 18) closed by bonded portion BDb is formed.

With semiconductor substrate 80b (FIG. 18) according to the present embodiment, bonded portion BDb greater in thickness than bonded portion BDa of semiconductor substrate 80a (FIG. 2) can be formed.

### Embodiment 5

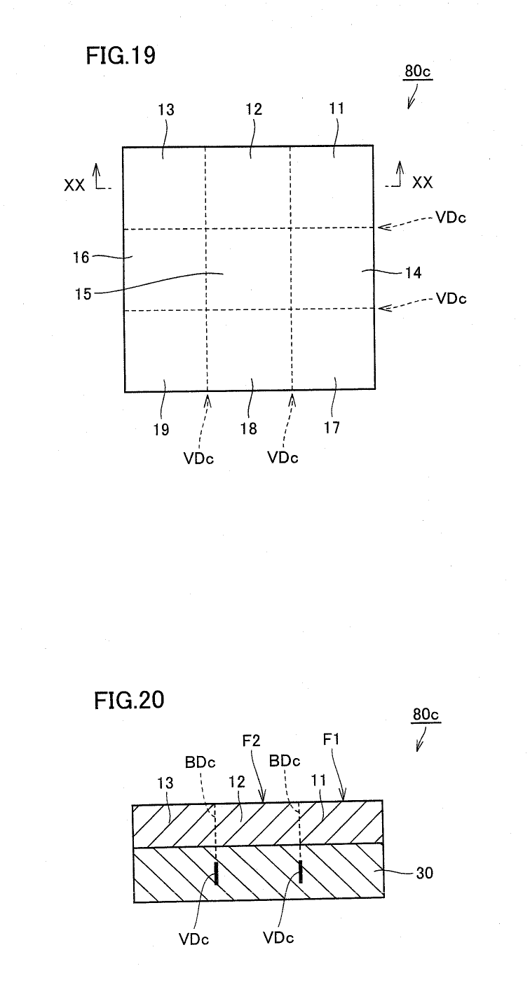

Referring to FIGS. 19 and 20, a semiconductor substrate 80c according to the present embodiment has a gap VDc closed by a bonded portion BDc instead of gap VDb (FIG. 18: Embodiment 4) closed by bonded portion BDb. Semiconductor substrate 80c is obtained by moving entire gap VDa (FIG. 2) into support portion 30 via a position of gap VDb (FIG. 18), with the method as in Embodiment 4.

According to the present embodiment, bonded portion. BDc further greater in thickness than bonded portion BDb in Embodiment 4 can be formed. It is noted that gap VDc may be moved to reach the back surface side (a lower side in FIG. 20). Thus, closed gap VDc becomes a recess on the back surface side. This recess may be removed by polishing.

### Embodiment 6

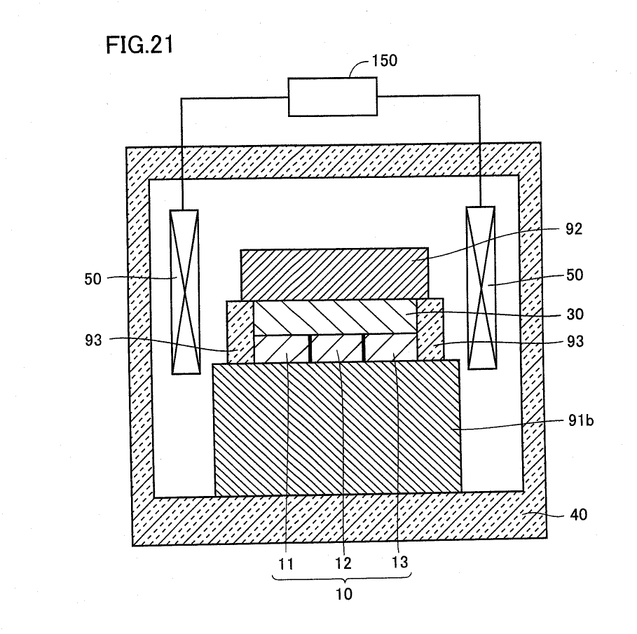

Referring mainly to FIG. 21, in the present embodiment, a heat insulator 93 is arranged to face SiC substrate group 10 in the third space (FIG. 7). Namely, instead of heat-insulating vessel 40, heat insulator 93 implements third radiation plane RP3. Heat insulator 93 is lower in thermal conductivity than a material forming second heating element 92, that is, second radiation plane RP2, and preferably lower in thermal conductivity than a material forming a first heating element 91b formed of a material the same as that for first heating element 91a (FIG. 5), that is, first radiation plane RP1. Such heat insulator 93 is formed, for example, of carbon felt.

According to the present embodiment, a temperature of third radiation plane RP3 can more reliably be lowered by means of heat insulator 93.

In addition, when a heat-insulating function of heat insulator 93 is sufficiently high, the temperature of third radiation plane RP3 formed by heat insulator 93 can be made lower than the temperature of second radiation plane RP2 even if heater 50 is located as shown in FIG. 21 with respect to SiC substrate group 10, that is, even if a part of heater 50 is located in third space SP3 (FIG. 7). Therefore, according to the present embodiment, a degree of freedom in arrangement of heater 50 is higher than in Embodiment 1.

### Embodiment 7

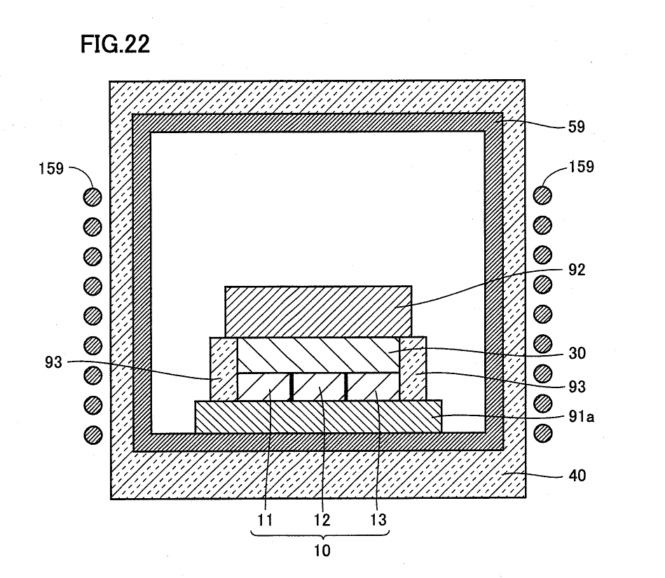

Referring to FIG. 22, a heating apparatus in the present embodiment is an induction heating furnace, and it has a heated element 59 (heat source) and a coil 159 instead of heater 50 (FIG. 5). Heated element 59 is, for example, a graphite crucible, and a substantially closed space is formed in heat-insulating vessel 40. In this closed space, first heating element 91a, second heating element 92, SiC substrate group 10, and support portion 30 are arranged. In addition, heat insulator 93 is arranged as in Embodiment 6.

In the heating step in the present embodiment, initially, heated element 59 generates heat as a result of induction heating by coil 159. As a result of this heat generation, first heating element 91a and second heating element 92 are heated.

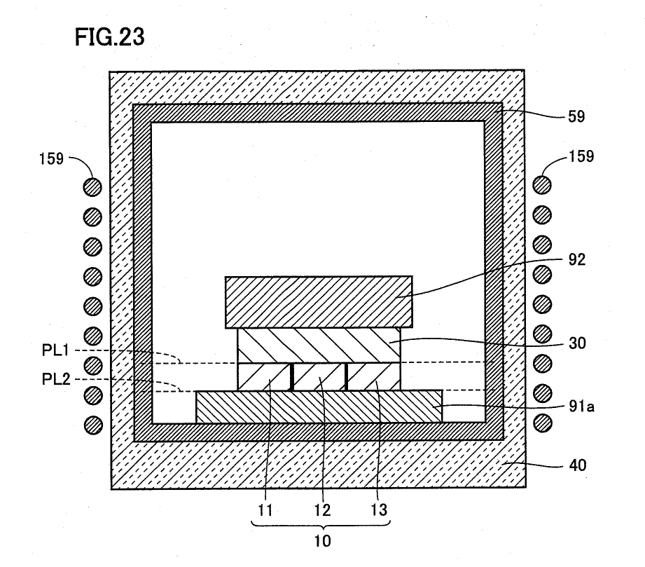

According to the present embodiment, in a case where an induction heating furnace is employed, the effect as in Embodiment 6 is obtained. If heat insulator 93 is not employed, the construction is as shown in FIG. 23, that is, third radiation plane RP3 (FIG. 7) being implemented by heated element 59. Therefore, as in the case of the construction in FIG. 10 (the comparative example of Embodiment 1), opening CR (FIG. 8) is less likely to be closed.

### Embodiment 8

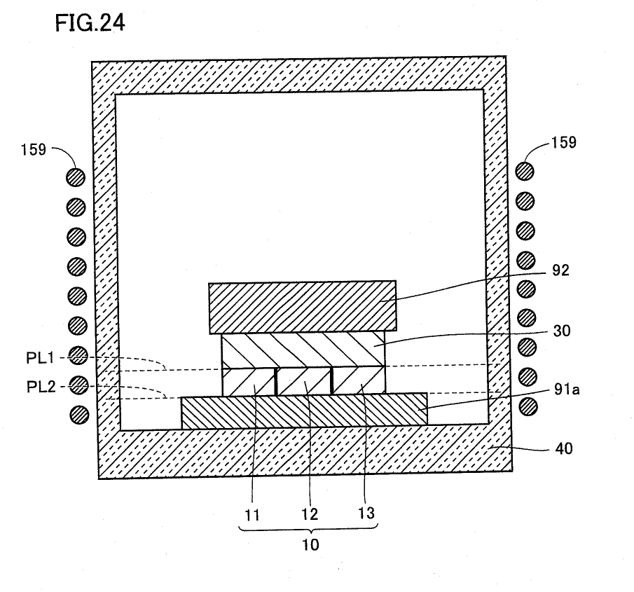

Referring to FIG. 24, in the present embodiment, unlike Embodiment 7, heated element 59 is not provided but first and second heating elements 91a and 92 are directly heated through induction heating.

According to the present embodiment, since heat radiation is achieved by the construction shown in FIG. 7 as in Embodiment 1, the effect as in Embodiment 1 is obtained.

### Embodiment 9

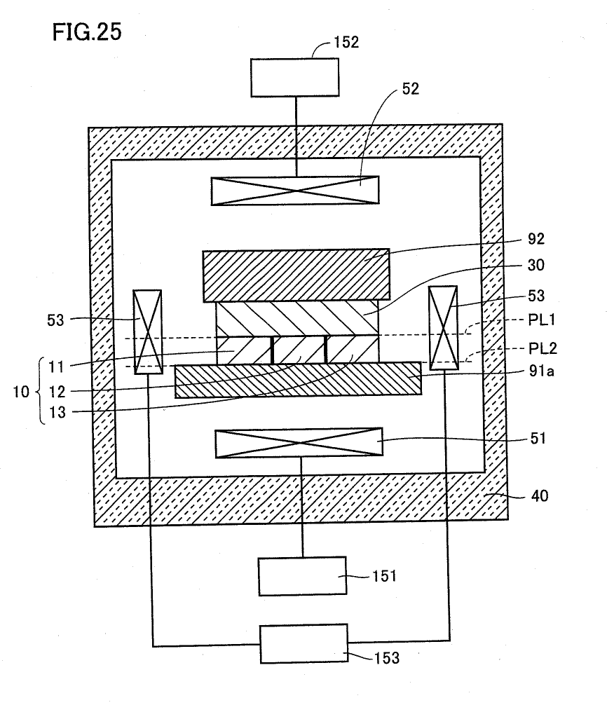

Referring to FIG. 25, a heating apparatus in the present embodiment has first to third heaters 51 to 53 (first to third heat generation elements) and first to third heater power supplies 151 to 153 for heating.

First to third heaters 51 to 53 are arranged in first to third spaces SP1 to SP3 (FIG. 7), respectively. It is noted that third heater 53 does not have to be arranged in third space SP3 in its entirety and at least a part thereof should only be arranged therein.

First to third heater power supplies 151 to 153 are connected so as to be able to independently control heat generation by first to third heaters 51 to 53. Thus, respective temperatures of the surfaces corresponding to first to third radiation planes RP1 to RP3 (FIG. 7) in the present embodiment, that is, the surface of first heating element 91a, the surface of second heating element 92, and the surface of third heater 53, can be controlled independently of one another. Therefore, the temperature corresponding to third radiation plane RP3 can be set lower than the temperature corresponding to second radiation plane RP2 but not excessively lower than that.

If temperature control as precise as above is not required, any or both of first heater 51 and third heater 53 may be eliminated.

### Appendix 1

The semiconductor substrate according to the present invention is fabricated with the following manufacturing method.

A plurality of silicon carbide substrates having first and second silicon carbide substrates and a support portion are prepared. The first silicon carbide substrate has a first back surface facing the support portion and located on one plane, a first front surface opposed to the first back surface, and a first side surface connecting the first back surface and the first front surface to each other. The second silicon carbide substrate has a second back surface facing the support portion and located on one plane, a second front surface opposed to the second back surface, and a second side surface connecting the second back surface and the second front surface to each other. The second side surface is arranged such that a gap having an opening between the first and second front surfaces is formed between the second side surface and the first side surface. The support portion and the first and second silicon carbide substrates are heated such that a sublimate is generated from the first and second side surfaces and a bonded portion closing the opening is formed thereby. The heating step has the following steps. A temperature of a first radiation plane facing the plurality of silicon carbide substrates in a first space extending from the plurality of silicon carbide substrates in a direction perpendicular to one plane and away from the support portion is set to a first temperature. A temperature of a second radiation plane facing the support portion in a second space extending from the support portion in a direction perpendicular to one plane and away from the plurality of silicon carbide substrates is set to a second temperature higher than the first temperature. A temperature of a third radiation plane facing the plurality of silicon carbide substrates in a third space extending from the gap along one plane is set to a third temperature lower than the second temperature.

It should be understood that the embodiments disclosed herein are illustrative and non-restrictive in every respect. The scope of the present invention is defined by the terms of the claims, rather than the description above, and is intended to include any modifications within the scope and meaning equivalent to the terms of the claims.

### INDUSTRIAL APPLICABILITY

The method of manufacturing a semiconductor substrate according to the present invention is particularly advantageously applicable to a method of manufacturing a semiconductor substrate including a silicon carbide substrate.

### DESCRIPTION OF THE REFERENCE SIGNS

10 SiC substrate group (a plurality of silicon carbide substrates); 10a supported layer; 11 SiC substrate (first silicon carbide substrate); 12 SiC substrate (second silicon carbide substrate); 13 to 19 SiC substrate; 20, 20p solid source material; 30, 30p support portion; 40 heat-insulating vessel; 59 heated element; 80a to 80c semiconductor substrate; 80P composite substrate; 81, 91a, 91b first heating element; 82, 92 second heating element; 93 heat insulator; 150 heater power supply; 151 to 153 first to third heater power supply; and 159 coil.

1. A method of manufacturing a semiconductor substrate, comprising the steps of:
preparing a plurality of silicon carbide substrates having first and second silicon carbide substrates and a support portion, said first silicon carbide substrate having a first back surface facing said support portion and located on one plane, a first front surface opposed to said first back surface, and a first side surface connecting said first back surface and said first front surface to each other, said second silicon carbide substrate having a second back surface facing said support portion and located on said one plane, a second front surface opposed to said second back surface, and a second side surface connecting said second back surface and said second front surface to each other, said second side surface being arranged such that a gap having an opening between said first and second front surfaces is formed between said second side surface and said first side surface; and
heating said support portion and said first and second silicon carbide substrates for generating a sublimate from said first and second side surfaces and thereby forming a bonded portion closing said opening,
said heating step including the steps of
setting a temperature of a first radiation plane facing said plurality of silicon carbide substrates in a first space extending from said plurality of silicon carbide substrates in a direction perpendicular to said one plane and away from said support portion, to a first temperature,
setting a temperature of a second radiation plane facing said support portion in a second space extending from said support portion in a direction perpendicular to said one plane and away from said plurality of silicon carbide substrates, to a second temperature higher than said first temperature, and
setting a temperature of a third radiation plane facing said plurality of silicon carbide substrates in a third space extending from said gap along said one plane to a third temperature lower than said second temperature.

2. The method of manufacturing a semiconductor substrate according to claim 1, wherein
said third temperature is lower than said first temperature.

3. The method of manufacturing a semiconductor substrate according to claim 1, wherein
said step of preparing said plurality of silicon carbide substrates and said support portion is performed by preparing a composite substrate having said support portion and said first and second silicon carbide substrates, and each of said first and second back surfaces of said composite substrate is bonded to said support portion.

4. The method of manufacturing a semiconductor substrate according to claim 1, further comprising the step of bonding each of said first and second back surfaces to said support portion, wherein
said step of bonding each of said first and second back surfaces is performed simultaneously with the step for forming said bonded portion.

5. The method of manufacturing a semiconductor substrate according to claim 1, wherein
said support portion is composed of silicon carbide.

6. The method of manufacturing a semiconductor substrate according to claim 5, further comprising the step of depositing a sublimate from said support portion on said bonded portion in said gap having said opening closed by said bonded portion.

7. The method of manufacturing a semiconductor substrate according to claim 6, wherein
said step of depositing a sublimate from said support portion on said bonded portion is performed such that said gap as a whole having said opening closed by said bonded portion moves into said support portion.

8. The method of manufacturing a semiconductor substrate according to claim 1, wherein
said heating step is performed with a heat source arranged outside said third space.

9. The method of manufacturing a semiconductor substrate according to claim 8, wherein
said heat source is arranged in a space including said support portion, of the spaces separated from each other by said third space.

10. The method of manufacturing a semiconductor substrate according to claim 1, wherein
a material forming said third radiation plane is lower in thermal conductivity than a material forming said second radiation plane.

11. The method of manufacturing a semiconductor substrate according to claim 10, wherein
the material forming said third radiation plane is lower in thermal conductivity than a material forming said first radiation plane.

12. The method of manufacturing a semiconductor substrate according to claim 1, wherein
said heating step is performed with first to third heat generation elements arranged in said first to third spaces respectively.

13. The method of manufacturing a semiconductor substrate according to claim 12, wherein
said first to third heat generation elements are controlled independently of one another.

14. The method of manufacturing a semiconductor substrate according to claim 1, wherein
each of said first and second front surfaces is a polished surface.

15. The method of manufacturing a semiconductor substrate according to claim 1, wherein
each of said first and second back surfaces is a surface formed by slicing.

16. The method of manufacturing a semiconductor substrate according to claim 1, wherein
said heating step is performed in an atmosphere having a pressure higher than 10⁻¹ Pa and lower than 10⁴ Pa.
